(19) United States
(12) Patent Application Publication
(10) Pub. No.: US 2014/0262031 A1
(43) Pub. Date: Sep. 18, 2014

(54) MULTI-MODE ETCH CHAMBER SOURCE ASSEMBLY

(71) Applicants: Sergey G. BELOSTOTSKIY, Sunnyvale, CA (US); Alexander MARCACCI, San Jose, CA (US); Kartik RAMASWAMY, San Jose, CA (US); Srinivas D. NEMANI, Sunnyvale, CA (US); Andrew NGUYEN, San Jose, CA (US); Yogananda SARODE, Bangalore (IN)

(72) Inventors: Sergey G. BELOSTOTSKIY, Sunnyvale, CA (US); Alexander MARCACCI, San Jose, CA (US); Kartik RAMASWAMY, San Jose, CA (US); Srinivas D. NEMANI, Sunnyvale, CA (US); Andrew NGUYEN, San Jose, CA (US); Yogananda SARODE, Bangalore (IN)

(21) Appl. No.: 13/893,199

(22) Filed: May 13, 2013

Related U.S. Application Data
(60) Provisional application No. 61/778,207, filed on Mar. 12, 2013.

(51) Int. Cl. H01J 37/32

(52) U.S. Cl. CPC H01J 37/3244; H01J 37/32091
USPC 156/345.28; 156/345.34; 239/548; 315/111.21

(57) ABSTRACT

A multi-chambered processing platform includes one or more multi-mode plasma processing systems. In embodiments, a multi-mode plasma processing system includes a multi-mode source assembly having a primary source to drive an RF signal on a showerhead electrode within the process chamber and a secondary source to generate a plasma with by driving an RF signal on an electrode downstream of the process chamber. In embodiments, the primary 7 source utilizes RF energy of a first frequency, while the secondary source utilizes RF energy of second, different frequency. The showerhead electrode is coupled to ground through a frequency dependent filter that adequately discriminates between the first and second frequencies for the showerhead electrode to be RF powered during operation of the primary source, yet adequately grounded during operation of the secondary plasma source without electrical contact switching or reliance on physically moving parts.

### CROSS REFERENCE TO RELATED APPLICATIONS

This application claims the benefit of U.S. Provisional Application No. 61/778,207 filed Mar. 12, 2013, titled “Multi-Mode Etch Chamber Source Assembly,” the entire contents of which are hereby incorporated by reference in its entirety for all purposes.

This application is related to U.S. patent application Ser. No. 13/651,074, filed Oct. 12, 2012, titled “Process Chamber for Etching Low K and Other Dielectric Films.”

### FIELD

Embodiments of the present invention pertain to the field of microelectronic device processing and, in particular, to plasma etch chamber energy source assemblies and showerheads.

### BACKGROUND

In semiconductor manufacturing, thin films are deposited on a workpiece workpiece (e.g., semiconductor wafer) and features are etched into the thin films. Such depositions and etches are often performed in a plasma processing chamber. Certain advanced plasma chambers, such as the etch chamber described in application Ser. No. 13/651,074, include two regions where plasmas are ignited and sustained, for example during different phases of a plasma etching process. This capability of the plasma processing chamber permits a first plasma to induce a first amount of self-bias on a workpiece disposed in the chamber, for example during a highly directional ion-induced process, while a highly selective chemically reactive mode can be achieved with a second plasma that exposes the workpiece to predominantly only reactive neutral species.

During a highly directional ion-induced process, it can be beneficial to have multiple frequencies of RF power applied. For example, a higher RF frequency RF source power may be delivered to a top electrode through which process gases are distributed into a first chamber volume (i.e., a first “showerhead”), while a lower frequency RF “bias” power is delivered to a support upon which a workpiece is disposed (i.e., a chuck, or pedestal). However, during the chemically reactive phase, it may be advantageous, at least with respect to stability, uniformity and reliability of the process, to have the chamber showerhead substantially grounded.

Thus, for advantageous performance, the showerhead is to be alternately RF powered and grounded, referred to herein as “multi-mode” source operation. A showerhead configured for such multi-mode operation is further referred to herein as a “multi-mode” showerhead. While such multi-mode operation may be accomplished by switching a coupling of the showerhead between a ground terminal and an RF powered terminal, to date, good uniformity of RF distribution across the showerhead and reliability of switched grounding and RF delivery remains difficult. As such, a plasma source assembly and showerhead assembly capable of reliably alternating between RF power delivery and grounded states is advantageous.

### BRIEF DESCRIPTION OF THE DRAWINGS

Embodiments of the present invention are illustrated by way of example, and not limitation, in the figures of the accompanying drawings in which:

FIG. 1 is a plan view of a multi-chambered processing platform that may be configured to include one or more etch chambers to perform a multi-operational mode etch process, in accordance with an embodiment;

FIG. 2A is an isometric view of a multi-mode plasma source assembly, that is employed in the one or more etch chambers in accordance with an embodiment;

FIG. 2B is an isometric view of a primary plasma source and a second plasma source of the multi-mode plasma source assembly depicted in FIG. 2A, in accordance with an embodiment;

FIG. 3 is an isometric view of a secondary plasma source assembly depicted in FIG. 2B, in accordance with an embodiment;

FIG. 4 is a sectional isometric view of the multi-mode plasma source assembly depicted in FIG. 2A, in accordance with an embodiment;

FIG. 5A is a cross-sectional side view of the multi-mode plasma source assembly depicted in FIG. 4 disposed on an etch chamber configured to perform a first plasma process with a first plasma generated in a first chamber region, in accordance with an embodiment;

FIG. 5B is a cross-sectional side view of the multi-mode plasma source assembly depicted in FIG. 4 disposed on an etch chamber configured to perform a second plasma process with a second plasma generated in a second chamber region, in accordance with an embodiment;

FIG. 6A is an expanded cross-sectional side view of a portion of the multi-mode plasma source assembly depicted in FIGS. 5A and 5B that is highlighted in FIG. 6B, in accordance with an embodiment;

FIG. 7A is an isometric view of a partially disassembled showerhead assembly illustrating a top surface of a showerhead sub-assembly; and

FIG. 7B is an isometric expanded view of the showerhead assembly depicted in FIG. 7A.

### DETAILED DESCRIPTION

In the following description, numerous details are set forth, however, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment,” or “in one embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention, or only one embodiment. Furthermore, the particular features, structures, functions, or characteristics may be combined in any suitable manner in one or more embodiments. For example, a first embodiment may be combined with a second embodiment anywhere the two embodiments are not specifically denoted as being mutually exclusive.

The term “coupled” is used herein to describe functional or structural relationships between components. “Coupled” may be used to indicated that two or more elements are in either direct or indirect (with other intervening elements between them or through the medium) mechanical, acoustic, optical, or electrical contact with each other, and/or that the two or more elements co-operate or interact with each other (e.g., as in a cause and effect relationship).

The terms “over,” “under,” “between,” and “on” as used herein refer to a relative position of one component or material layer with respect to other components or layers where such physical relationships are noteworthy for mechanical components in the context of an assembly, or in the context of material layers of a micromachined stack. One layer (component) disposed over or under another layer (component) may be directly in contact with the other layer (component) or may have one or more intervening layers (components). Moreover, one layer (component) disposed between two layers (components) may be directly in contact with the two layers (components) or may have one or more intervening layers (components). In contrast, a first layer (component) “on” a second layer (component) is in direct contact with that second layer (component).

In embodiments, a multi-chambered processing platform includes one or more multi-mode plasma processing systems to perform a multi-operational mode plasma process. The exemplary embodiments described in detail herein are described in the specific context of a multi-mode plasma etch system, however it is to be understood that the same components and assemblies may be implemented in a similar manner to achieve similarly variable plasma conditions useful in other plasma processing, such as a plasma deposition. As shown in FIG. 1, one or more multi-mode plasma etch systems 405, configured as further described elsewhere herein, are coupled together as an integrated multi-module processing platform 400. Referring to FIG. 1, the multi-chambered processing platform 400, may be any platform known in the art that is capable of adaptively controlling a plurality of process modules simultaneously. Exemplary embodiments include an Opus™ AdvantEdge™ system, a Producer™ system, or a Centura™ system, all commercially available from Applied Materials, Inc. of Santa Clara, Calif.

The processing platform 400 may further include an integrated metrology (IM) chamber 425 to provide control signals to allow adaptive control of any of the etch processes described herein. The IM chamber 425 may include any metrology commonly known in the art to measure various film properties, such as thickness, roughness, composition, and may further be capable of characterizing grating parameters such as critical dimensions (CD), sidewall angle (SWA), feature height (HT) under vacuum in an automated manner. As further depicted in FIG. 1, the multi-chambered processing platform 400 further includes load lock chambers 430 holding front opening unified pods (FOUPS) 435 and 445, coupled to the transfer chamber 401 having a robotic handler 450.

One or more multi-operational mode etch processes, such as a low-k dielectric etch process, may be performed by each etch system 405. As the etch process performed in the etch systems 405 may employ multiple distinct plasmas, the etch systems 405 may automatically cycle through a process sequence where plasmas are alternately sustained in different regions within a processing chamber as commands are executed by the controller 470. The controller 470 may be configured as a controller of only one etch system 405, or may be configured to similarly control a plurality of the etch systems 405. The controller 470 may be one of any form of general-purpose data processing system that can be used in an industrial setting for controlling various subprocessors and subcontrollers integral to the etch systems 405. Generally, the controller 470 includes a central processing unit (CPU) 472 in communication with a memory 473 and an input/output (I/O) circuitry 474, among other common components. Software commands executed by the CPU 472, cause the multi-chambered processing platform 400 to, for example, load a substrate into one the etch system 405, execute a multi-operation mode etch process, and unload the substrate from the etch system 405. As known in the art, additional controllers of the robotic handler 450, or load lock chambers 430 may be provided to manage integration of multiple etch systems 405.

FIG. 2A is an isometric view of a multi-mode plasma source assembly 200, in accordance with an embodiment. In the exemplary embodiment, the source assembly 200 forms a portion of an etch system (e.g., etch system 405 in FIG. 1) and provides a plurality of plasmas from which etchant species are generated for use in a process chamber. Such a multi-mode plasma source assembly may of course also find application in other plasma processing systems (e.g., deposition, etc.). In embodiments, a multi-mode plasma source includes both a primary plasma source and a secondary plasma source. Generally, the primary plasma source is to capacitively drive a showerhead electrode within the process chamber in which the workpiece is disposed while the secondary plasma source is to generate a plasma outside of the process chamber in which the workpiece is disposed (i.e., the secondary plasma source is a downstream source).

In advantageous embodiments, the primary plasma source utilizes RF energy of a first frequency, while the secondary plasma source utilizes RF energy of second frequency that is different than the first frequency. In advantageous embodiments, the first and second frequencies are in RF bands that are at least one order of magnitude apart, advantageously many orders of magnitude apart. In exemplary embodiments, the primary plasma source utilizes RF energy of a frequency of at least 13.56 MHz, advantageously at least 27 MHz, and more advantageously at least 50 MHz (e.g., 60-62 MHz). In these exemplary embodiments, the secondary plasma source utilizes RF energy of a frequency of no more than 1 MHz, advantageously less than 500 kH, and more advantageously no more than 100 kHz (e.g., 70 kHz).

Delivering the higher RF frequencies to the showerhead electrode has many advantages for both etching a workpiece and for dechucking the workpiece from an electrostatic chuck after an etch process. The high RF frequency (e.g., 60 MHz) of the primary plasma source however is further leveraged in embodiments herein as also being a distinguishing characteristic relative to the secondary plasma source since the secondary plasma is generated by driving a secondary electrode (e.g., capacitively) at the different (lower) frequency (e.g., 70 kHz). Therefore, across the modes of operation, when the primary and secondary plasma sources are alternately sustaining a plasma, the RF energy applied through the multi-mode plasma source changes frequency significantly. As described further herein, embodiments couple the showerhead electrode to ground through a frequency dependent filter that adequately discriminates between the first and second RF frequencies, enabling the showerhead electrode to be both RF powered during operation of the primary plasma source and adequately grounded during operation of the secondary plasma source without switching or reliance on physically moving parts. For the exemplary embodiments where the primary plasma source employs a high RF frequency while the secondary plasma source employs a low RF frequency, the showerhead electrode is coupled to ground through a coupler that serves as low pass filter. Such a filter may, for example, have a 30 dB cutoff frequency below the high RF frequency of the primary source. Such a low-pass filter may provide a coupling to ground with a sufficiently high inductance to pose a high impedance path for the high frequency RF (i.e., a coupling is functionally high frequency RF choke), while the low impedance path presented at the low frequency RF renders the showerhead electrode effectively grounded relative to a secondary RF electrode that is driven as the secondary plasma source.

Proceeding with the description of FIG. 2A, the assembly 200 includes a process chamber lid 205 to which an outer RF bell 210 is affixed. The lid 205 is to be affixed to a process chamber (not depicted) that is maintained at a reference potential (e.g., ground). The lid 205 is generally electrically conductive and is for example made of a metal, such as, but not limited to, aluminum. As visible in FIG. 2A, the outer RF bell 210 has an annular top surface 211 with an outer sidewall 212 making physical and electrical contact to the chamber lid 205. Generally, the outer RF bell 210 is of an electrically conductive material, and in the exemplary embodiment is aluminum, although other materials are also possible.

Affixed to the outer RF bell 210 are a plurality of RF rod tubes 215A, 215B, 215N separated by an azimuth angle φ. The RF rod tubes 215A, 215B, 215N standoff an RF distribution plate 220 disposed over the outer RF bell 210. Disposed over the RF distribution plate 220 is an RF match 230. Inner and outer process gas lines 255, 260 extend into an interior region of the source assembly 200 that is surrounded by the outer RF bell 210. Heat transfer fluid lines 242 (e.g., an input and output pair) similarly extend between a coolant block 240 affixed to the chamber lid 205 and an interior region of the source assembly 200 for transporting a liquid, such as an ethylene glycol/water mix, etc.

FIG. 2B is an isometric view of a primary plasma source assembly 270 and a secondary plasma source assembly 275 of the multi-mode plasma source assembly 200, in accordance with an embodiment. As shown, the primary plasma source assembly 270 can be lifted off the chamber lid 205 without disassembling the primary plasma source assembly 270 (e.g., by removal of the screws at the base of the outer RF bell sidewall 212). With the primary plasma source assembly 270 lifted off the chamber lid 205, the secondary plasma source assembly 275 disposed within the interior region of the source assembly 200 is visible in FIG. 2B. When assembled, the secondary plasma source assembly 275 is therefore surrounded by the toroid-shaped outer RF bell 210.

The secondary plasma source assembly 275 is disposed over a showerhead assembly 280, which includes a disc-shaped showerhead sub-assembly (not visible in FIG. 2B) that is open to an interior of the process chamber. In the exemplary embodiment the secondary plasma source assembly 275 is centered on a center of the showerhead assembly 280 (i.e., aligned with a center of the showerhead, represented in FIG. 2B by the dashed longitudinal axis Zₒ). The outer RF bell 210 therefore is also centered on the Zₒ axis. The showerhead assembly 280 further includes an annular electrically insulative spacer 282 that is to make physical contact with the chamber lid 205 and provide a highly resistive path between electrically conductive components of the showerhead assembly 280 and the electrically conductive chamber lid 205. Generally, the spacer 282 is of a dielectric material, such as aluminum oxide, another ceramic, etc. Disposed over the spacer 282 is a facility plate 285. In the exemplary embodiment, the facility plate 285 is affixed in direct contact with the spacer 282. The facility plate 285 functionally is to provide lands for the heat transfer fluid lines 242, and/or process gas lines, and/or other facilities, such as sensor probe fittings, or the like.

The facility plate 285 may further have one or more heater (AC)/pass-throughs, heat transfer fluid conduits, and/or gas conduits embedded therein, as described further elsewhere herein.

In the exemplary embodiment, the facility plate 285 is of at least one electrically conductive material, which is in the exemplary embodiment aluminum, but may be of other materials (e.g., metals) of similarly low electrical resistivity. As shown in FIG. 2B, the showerhead assembly further includes an annular contact ring 290 disposed over the facility plate 285 to be in electrical contact with the facility plate 285. In the exemplary embodiment, the annular contact ring 290 is affixed directly to a top surface of the facility plate 285 to stand-off and electrically couple a powered electrode to the facility plate.

FIG. 3 is an isometric view further illustrating the secondary plasma source assembly 275, in accordance with an embodiment. As shown, the secondary plasma source assembly 275 includes a source cover 310, which is affixed to the facility plate 285 and makes a seal with a top surface of a gas block 315. The source cover 310 further includes an RF line pass through (not visible) and a gas fitting 261 for receiving the outer gas line 260 and providing a fluid coupling to one or more gas conduit channels within the gas block 315. The source cover 310 has sidewalls with edges that make contact with the facility plate 285 and being of a conductive material, such as aluminum, the source cover 310 maintains a same electrical potential as a top surface the facility plate 285 disposed within the major diameter of the toroid-shaped outer RF bell 210. The one or more channels in the gas block 315 are in fluid communication with one or more gas lines 320 that conduct fluid between the gas block 315 and fittings in the facility plate 285. Disposed between the gas block 315 and a secondary RF electrode 330 is an electrically insulative material, such as Al₂O₃, alternate ceramic, high temperature plastics, etc.

The secondary RF electrode 330 is to be driven with the secondary RF signal (e.g., <1 MHz), as previously discussed. The secondary RF electrode 330 is generally annular in shape to surround, and be in electrical contact with, an RF powered electrode nozzle 340. The RF powered electrode nozzle 340 is RF powered and may therefore be of any material of sufficient conductivity to be powered along with the secondary RF electrode 330. The nozzle 340 may be aluminum, or other material as a function of the plasma processing (e.g., etching) to be performed. For example, in one embodiment the RF powered electrode nozzle 340 is silicon. The RF powered electrode nozzle 340 is disposed within an annular electrical insulator 350, which in turn is disposed in contact with the facility plate 285. The electrical insulator 350, of a dielectric material such as Al₂O₃ is to physically support the secondary RF electrode 330 while providing electrical isolation between the facility plate 285 and the secondary RF electrode 330. The electrical insulator 350 further comprises a fitting for receiving the inner gas line 255.

FIG. 4 is a sectional isometric view of the multi-mode plasma source assembly 200, in accordance with an embodiment. As can be seen in this view, the outer RF bell 210 is “folded” such that the top surface 211, outer sidewall 212 and inner sidewall 213 form three sides of a toroid with a cavity therein. Disposed within the sectional area of the outer RF bell 210 (i.e., within the minor radius) is an inner RF bell 496. The inner RF bell 496 is annular in shape, forming a continuous ring that is in electrical contact with the outer RF bell 210 proximate to an edge of the inner sidewall 213. The inner RF bell 496 is of an electrically conductive material suitable for transmission of RF energy at the first (high) frequency. In the exemplary embodiment the inner RF bell 496 is of aluminum, but other materials (metals, etc.) are also possible. Also visible in FIG. 4 is the showerhead assembly 280 and the components of the secondary plasma source 275.

FIG. 5A provides a cross-sectional side view of the multi-mode plasma source assembly 200 disposed on a plasma processing chamber 600 and generating a first plasma 670 within a chamber region proximate a workpiece 302, in accordance with an embodiment. FIG. 5B further depicts the multi-mode plasma source assembly 200 disposed on the plasma processing chamber 600 and performing a second plasma process with a second plasma 692 within a second chamber region distal from the workpiece 302, in accordance with an embodiment. The controller 470 is again to alternately energize the first and second plasmas 670 and 692 during a plasma process (e.g., etching).

As shown in FIG. 5A, the first plasma 670 is driven with RF energy supplied by the generator 628, operating for example at 27 MHz, or above, and advantageously of at least 50 MHz. The chamber 600 has grounded chamber 640 surrounding a chuck 650. The chamber 640 is electrically connected to the chamber lid 205. In embodiments, the chuck 650 is an electrostatic chuck (ESC) which clamps the workpiece 302 to a top surface of the chuck 650 during processing, though other clamping mechanisms known in the art may also be utilized. The chuck 650 may be movable along the longitudinal chamber axis a distance DH₂, for example by way of a bellows 655. The chuck 650 includes an embedded heat exchanger coil 617. In the exemplary embodiment, the heat exchanger coil 617 includes one or more heat transfer fluid channels through which heat transfer fluid, such as an ethylene glycol/water mix, may be passed to control the temperature of the chuck 650 and ultimately the temperature of the workpiece 302. The chuck 650 includes a mesh 649 coupled to a high voltage DC supply 648 so that the mesh 649 may carry a DC bias potential to implement the electrostatic clamping of the workpiece 302. The chuck 650 may be coupled to another RF power source and in one such embodiment, the mesh 649 is coupled to a chuck RF power source so that both the DC voltage offset and the RF voltage potentials are coupled across a thin dielectric layer on the top surface of the chuck 650. In the illustrative embodiment, the chuck RF power source includes a first and/or second RF generator 652, 653. The RF generators 652, 653 may operate at any industrial frequency typical in the art, however in the exemplary embodiment the RF generator 652 operates at 13.56 MHz while a second RF generator 653 is operable at an exemplary frequency of 2 MHz. One or both of the RF generators 652, 653 may be operated at any given time and in certain embodiments only one of generators 652, 653 may be present. A DC plasma bias (i.e., RF bias) resulting from capacitive coupling of the RF powered chuck may generate an ion flux from the first plasma 670 to the workpiece 302 (e.g., Ar ions where the first feed gas is Ar) to provide a directional plasma treatment (e.g., etching, milling, etc.).

As further illustrated in FIG. 5A, the etch chamber 600 includes a pump stack capable of high throughput at low process pressures. In embodiments, at least one turbo molecular pump 665, 666 is coupled to the first chamber region 684 through a gate valve 660 and disposed below the chuck 650, opposite the multi-mode RF source 200. The turbo molecular pump(s) 665, 666 may be any commercially available having suitable throughput and more particularly is to be sized appropriately to maintain process pressures below 10 mTorr and preferably below 5 mTorr at the desired flow rate of the first feed gas (e.g., 50 to 500 sccm of Ar). In the embodiment illustrated in FIG. 6A, the chuck 650 forms part of a pedestal which is centered between the two turbo pumps 665 and 666, however in alternate configurations chuck 650 may be on a pedestal cantilevered from the chamber wall 640 with a single turbo molecular pump having a center aligned with a center of the chuck 650.

As shown in FIG. 5B, the second plasma 692 is driven with RF energy supplied by the generator 608, operating for example at 1 MHz, or less, and advantageously below 100 kHz. Advantageously, the second plasma 692 may not provide any significant RF bias potential on the chuck 650. In certain embodiments therefore, the second plasma 692 may be considered a “downstream” plasma.

FIG. 6A is an expanded cross-sectional side view of a portion of the multi-mode plasma source assembly 200 that is highlighted by dased line in FIG. 6B, in accordance with an embodiment. As shown in FIG. 6A, the first (high frequency) source assembly includes an RF path that passes through an RF rod 613 that receives RF energy from the RF distribution plate 220. The RF rod 613 passes through cuttings in the outer RF bell 210 and is electrically isolated at the cuttings by an insulative sheath, made of, for example, a plastic (e.g., PTFE), ceramic, etc. The RF rod 613 makes contact with a top surface of the inner RF bell 496. As visible in FIG. 6A, the inner RF bell 496 makes an inward bend to make physical contact with the inner sidewall 212 of the outer RF bell 210. The inward (clockwise) bend of the inner RF bell 496, the outward (clockwise) bend of the outer RF bell between the inner sidewall 212 and top surface 211, and the downward (clockwise) bend between the top surface 211 and outer sidewall 213 may provide one or more of a desired transmission line length and a complete coil turn having a desired impedance/inductance.

In embodiments, the path length provided by the surfaces of the outer RF bell 210 is a function of the quarter-wave length of at least the high frequency RF energy supplied through the RF rods 613. More specifically, in certain embodiments the cumulative length of the surfaces of the outer RF bell 210 between the inner sidewall edge and the outer sidewall edge is a multiple of the quarter-wavelength of the high frequency RF to form an open circuit transmission line stub (RF open circuit that is a DC short circuit) and also a low impedance circuit for the low frequency RF signal employed to power the electrode 330.

In certain embodiments however, the dimensions and folded geometry of the outer RF bell 210 provides sufficient inductance for frequency dependent isolation from the chamber lid 205 without reliance on forming an open circuit transmission line stub. With properly chosen conductivity of the inner and outer RF bells, 496, 210 (e.g., proper material and material thickness), an inductance (reactance) associated with the stub will advantageously attenuate the high frequency RF path to the chamber lid 205 (coupled to ground potential through the chamber 640) even if not dimensioned to be on a quarter wave length of the high frequency RF signal.

In embodiments, the toroid shape of the RF bells 210, 496 prevent high frequency RF power introduced through the RF rods 613 from penetrating to the interior region within the major diameter of the toroid, creating a virtual ground in the center portion of the top surface of the showerhead assembly 280 (i.e., top surface of the facility plate 285).

With the outer RF bell 210 functioning as a transmission line stub, a low impedance high frequency RF path is provided between the contact ring 290 and the RF bells 496, 210. As shown in FIG. 6B, there is a physical gap 662 between the inner sidewall 213 and the contact ring 290, which accommodates cumulative machining tolerances (i.e., tolerance stack-up) associated with the various assemblies and also accommodates o-ring expansion and/or strain between evacuated assembly portions, such as the showerhead assembly 280, and those portions of the assembly maintained at a static equilibrium pressure. To provide electrical contact between the contact ring 290 and the RF bells 496, 210 an RF gasket is disposed within the gap 662. The high frequency RF path of lowest impedance then extends to the contact ring and into the showerhead assembly 280 where it is conducted to the showerhead electrode 699.

As further shown in FIG. 6A, the RF powered electrode nozzle 340 associated with the secondary plasma source (e.g., low frequency) is disposed within a center portion of the showerhead assembly 280 with an annular electrically insulative ring 645 disposed between the electrode nozzle 340 and the facility plate 285. The insulative ring 645, being of a dielectric material, such as, but not limited to quartz, Al₂O₃, or other ceramics, physically stands-off and electrically isolates the RF powered electrode nozzle 340 from the remainder of the showerhead assembly 280 (the majority of which is electrically conductive). As shown in the cross-sectional view of FIG. 6A, and further in the isometric view of FIG. 7A, the insulative ring 645 is surrounded by the facility plate 285, forming a pocket to receive one end of the RF powered electrode nozzle 340. In the exemplary embodiment shown in FIG. 6A, the RF powered electrode nozzle 340 is itself annular in shape with a conical interior surface forming a conical interior cavity, the larger end of which is proximate to the insulative ring 645. Although not visible in FIG. 6A, the interior cavity volume is fluidly coupled to a gas inlet that is fitted to the inner process gas line 255.

As also shown in FIG. 6A, the exemplary facility plate 285 includes one or more heat transfer fluid conduits 686. Fluid conduits 686 are in fluid communication with the heat transfer fluid lines 242. One or more process gas conduits 687 are also disposed in the facility plate 285, which form a perimeter around the heat transfer fluid conduit and are in fluid communication with the gas lines 320, extending from the gas block 315.

In the exemplary embodiment, the facility plate 285 is annular rather than a continuous disc with a gas permeable disc 676 disposed at a center of the facility plate 285, aligned with a center of the RF powered electrode nozzle 340. Although a solid disc-shaped facility plate is also compatible with the multi-mode plasma source embodiments described herein, the exemplary configuration further permits selection of the material exposed to reactive species generated by the secondary plasma independent of the facility plate 285. The separation of the disc 676 from the facility plate 285 has further advantages, such as allowing for independent replacement if consumed. The gas permeable disc 676 includes openings through which reactive species (e.g., neutrals) generated by the secondary plasma 692 pass into through holes in an interior portion of a showerhead sub-assembly 298 (visible in FIG. 7A). The disc 676 is advantageously of an electrically conductive material, such as, but not limited to, aluminum or silicon. Sidewalls of the disc 676 are in electrical contact with the facility plate 285, or another conductive portion of the showerhead sub-assembly 298, and in the exemplary embodiment the disc 676 includes an overhanging top lip so as to be retained within the facility plate 285 when the facility plate 285 is lifted from the showerhead sub-assembly 298 (as is further depicted in FIG. 7A).

The showerhead assembly 280 further includes the showerhead sub-assembly 698. Generally, the showerhead sub-assembly 698 may be any conventional single-plate showerhead or multi-plate showerhead because the function and structure of the multi-mode plasma source embodiments described herein are not dependent on the particular construction of the showerhead sub-assembly 698. In embodiments, the showerhead assembly sub-assembly is disc-shaped and of electrically conductive material(s) having sufficiently low resistance to transmit RF energy received from either the first or second plasma sources (i.e., high or low frequency signals). In further embodiments, the showerhead sub-assembly may comprise one or more zones (e.g., a dual zone showerhead is described in U.S. patent application Ser. No. 12/836,726, commonly assigned).

In the exemplary embodiment depicted in FIGS. 6A and 7A, the showerhead sub-assembly 698 includes one or more metal (e.g., aluminum) plates arranged in a stack (e.g., e-beam welded together) to provide one or process gas conduits that are in fluid communication either a process gas conduit in the facility plate 285, or with the disc 676. The showerhead sub-assembly 698 further comprises one or more electrically insulative rings 680 forming a perimeter of the sub-assembly 298, o-ring seats, and fittings, etc. As shown in FIG. 6A, the bottom plate of the showerhead sub-assembly 698 is the showerhead electrode 699, which is of a conductive material further suitable for exposure to plasma in the process chamber. In the exemplary embodiment, the showerhead electrode 699 is silicon, but may be any material known to be suitable for the particular plasma processing (e.g., etching) to be performed within the processing chamber volume.

The annular insulative spacer 282 surrounding the showerhead sub-assembly 698, further visible in FIG. 6A, provides a path of high electrical resistance from the showerhead sub-assembly 698 to the chamber lid 205. Also visible in FIG. 6A is a physical gap 663 between the facility plate 285 and the inner, outer RF bells 496, 210 such that the path of lowest electrical resistance to ground is through the contact ring 290 and the outer RF bell 210 (via RF gasket). Hence, the outer RF bell 210 provides electrical grounding of the electrode relative to the RF driven components in secondary plasma RF source 275. While the geometry of the outer RF bell may be made a multiple of a quarter wavelength of the secondary RF signal such that the outer RF bell 210 forms a transmission line stub approximating an electrical short circuit at the frequency of the secondary RF signal, it has been found sufficient to merely tune the inductance of the RF bell 210 so that the cutoff frequency permits passage of the secondary RF signal. Whether based on inductance tuning or transmission line stub theory, the showerhead assembly 280 and outer RF bell 210 are dimensioned to function as a continuous electrical ground plane when the secondary electrode 330 is energized to generate the second plasma 692.

FIG. 7A is an isometric view of a partially disassembled showerhead assembly 280 illustrating a top surface of the exemplary showerhead sub-assembly 298. With the secondary plasma source 275 and the disc 676 removed along with the facility plate 285, regions and components of the showerhead sub-assembly 298 are visible. In particular, first showerhead openings disposed within an inner region 710 of the top surface of the sub-assembly 298 are surrounded by second openings 715 disposed within an annular region of the top surface, and contained by gas seals 718. The second openings 715 are in fluid communication with the gas block 315, via the gas lines 320 and the fluid conduit 687 embedded in the facility plate 285.

In some embodiments, the annular electrically insulative ring 730 may be disposed over, or embedded in, the top surface to surround the inner showerhead region 710 forming a dielectric spacer between the disc 676 and the inner showerhead region 710. The ring 730 may be of a number of dielectric materials, such as Al₂O₃, other ceramics, quartz, etc., or it may be completely absent, depending on the process performed in the processing chamber. A gas seal 719 (e.g., o-ring groove/o-ring) surrounds the ring 730/inner region 710.

FIG. 7B is an isometric expanded view of the showerhead sub-assembly 698, again with the disc 676 removed. As shown, the facility plate 285 is disposed over the insulative ring 680 and a showerhead base 727 configured to provide a process gas reservoir behind the showerhead electrode 699. Thermal gaskets 737 thermally couple and physically stand-off the showerhead base 727 from the showerhead electrode 699. Finally, the showerhead electrode 699 is seated into a clamp ring 747, which is affixed to the insulative dielectric ring 282.

It is to be understood that the above description is intended to be illustrative, and not restrictive. For example, while diagrams show a particular order of components stacked up in certain embodiments of the invention, it should be understood that such order is not necessarily required to achieve the functionality of the system (e.g., alternative embodiments may have different physical relationships, combine certain structures into one, separate certain structures into discrete components, overlap certain structures in different manners, etc.). Furthermore, many other embodiments will be apparent to those of skill in the art upon reading and understanding the above description. Therefore, although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. A multi-mode plasma processing chamber showerhead assembly, comprising:
an electrically conductive disc-shaped showerhead sub-assembly with first openings disposed within an inner region of a top surface of the sub-assembly and second openings disposed within an annular region of the top surface surrounding the first openings;
an electrically conductive facility plate disposed over, and in electrical contact with, the showerhead, the facility plate including a heat transfer fluid conduit; and
an annular dielectric ring positioned between the inner region and annular regions to stand-off and electrically insulate a powered electrode from the facility plate and the top surface of the showerhead sub-assembly.

2. The showerhead assembly of claim 1, wherein the facility plate further comprises a gas conduit in fluid communication with the second openings and forming a perimeter around the heat transfer fluid conduit, the gas conduit having a gas inlet to receive a first process gas fitting.

3. The showerhead assembly of claim 1, wherein the facility plate is an annular ring, forming a perimeter surrounding the inner region of the showerhead; and
the assembly further comprising a fluid permeable disc disposed within an inner diameter of the facility plate and disposed over the first openings in the showerhead sub-assembly, the disc in electrical contact with the facility plate.

4. The showerhead assembly of claim 1, further comprising:
an electrically conductive annular contact ring affixed to a top surface of the facility ring and surrounding the inner region.

5. A first plasma source, comprising:
the showerhead assembly of claim 1; and
a secondary electrode to receive RF energy and disposed over showerhead assembly, the secondary electrode electrically insulated from the showerhead assembly by the annular dielectric ring.

6. The plasma source assembly of claim 5, wherein the top electrode is annular with a conical interior surface having a largest diameter at an end of the top electrode proximate to the fluid permeable disc and with the interior volume of top electrode fluidly coupled to a second gas inlet to receive a second process gas fitting.

7. A multi-mode RF source assembly, comprising:
an electrically conductive showerhead assembly affixed to an annular dielectric spacer that is to affixed to component of a grounded process chamber, the dielectric spacer providing electrical insulation between the chamber component and the showerhead assembly;
a first plasma source to drive the showerhead assembly with a first RF signal of a first frequency through an electrically conductive coupler; and
a second plasma source to drive a secondary electrode with a second RF signal of a second frequency, wherein the coupler further provides an electrical path to the process chamber, the electrical path being of sufficiently high impedance at the first frequency for the first RF source to energize the showerhead assembly relative to the process chamber and of sufficiently low impedance at the second frequency for the second RF source to energize the secondary electrode relative to the showerhead assembly and the process chamber.

8. The multi-mode RF source assembly of claim 7, wherein the first frequency is greater than the second frequency with the coupler operative as a low pass filter having a cutoff frequency below the first frequency.

9. The multi-mode RF source assembly of claim 8, wherein the first frequency is at least 27 MHz, and wherein the second frequency not more than 1 MHz.

10. The multi-mode RF source assembly of claim 7, wherein the coupler comprises a toroid having a center aligned to a center of the showerhead assembly and having a top surface between inner and outer sidewalls, the inner sidewall electrically connected to the showerhead assembly and the outer sidewall electrically connected to the chamber component.

11. The multi-mode RF source assembly of claim 10, further comprising:
a plurality of RF rods passing through the coupler top surface;
an electrically conductive annular ring disposed within a cavity between the inner and outer sidewalls, the ring electrically connected to a first end of each of the plurality of RF rods, and electrically connected to the inner sidewall of the coupler;
an RF distribution plate disposed over the coupler top surface and electrically connected to a second end of the RF rods, the RF distribution plate including an RF input coupled to a first RF source.

12. The multi-mode RF source assembly of claim 7, wherein the showerhead assembly further comprises:
a disc-shaped showerhead;
an electrically conductive facility plate affixed to a top surface of the showerhead;
an electrically conductive annular contact ring affixed to a top surface of the facility plate; and
an RF gasket disposed between the inner sidewall of the coupler and an outer sidewall of the contact ring.

13. The multi-mode RF source assembly of claim 12, further comprising:
a first gas feed coupled into a conical cavity defined by an inner sidewall surface of the secondary electrode; and
a second gas feed coupled into a gas block disposed over the first plasma source, the gas block in fluid communication with openings in the showerhead top surface proximate an outer perimeter of the showerhead.

14. The multi-mode RF source assembly of claim 12, wherein the inner sidewall of the coupler is spaced apart from a top surface of the facility plate.

15. A multi-mode plasma etch system, comprising:
a grounded process chamber;
a chuck disposed within the chamber to support a workpiece during an etching process; and
the multi-mode RF source assembly of claim 7.

16. The multi-mode plasma etch system of claim 15, wherein the chuck is to be driven by a third RF energy source of a third frequency that is between the first and second frequencies to capacitively energize a first plasma of the first feed gas within a first chamber region between the showerhead assembly and the chuck.

17. The multi-mode plasma etch system of claim 15, further comprising:
a controller to alternately energize first and second plasmas during a plasma etching process by alternately driving the first RF signal on the showerhead and the second RF signal of the second frequency on the secondary electrode.
